(19) United States
(12) Patent Application Publication
(10) Pub. No.: US 2004/0016393 A1
(43) Pub. Date: Jan. 29, 2004

(54) Apparatus and method for conducting experiments and performing processes in a microgravity environment

(76) Inventor: Daniel C. Carter, Huntsville, AL (US)

Correspondence Address: LARSON & TAYLOR, PLC, 1199 NORTH FAIRFAX STREET, SUITE 900, ALEXANDRIA, VA, 22314, US

(21) Appl. No.: 10/200,493

(22) Filed: Jul. 23, 2002

(51) Int. Cl. C30B 7/00; C30B 21/02; C30B 28/06

(52) U.S. Cl. 117/68

(57) ABSTRACT

An apparatus and method for the containment of supplies, experiments or other physical or chemical processes or reactions to be carried out in microgravity environments is provided which features a hollow canister having at least one closure means at either the bottom end or top end of the canister and an endcap with two o-rings to provide a second level of containment. The canister further contains at least one assembly for performing microgravity experiments and is advantageous in that it allows secure stowage of assemblies for conducting microgravity experiments yet also allows easy access to the assemblies in order to activate them when a microgravity environment is achieved. The apparatus also allows for safely and simple visualizing the experiments being conducted in the microgravity environment, and the dual levels of containment protect against hazardous leakage.

### BACKGROUND OF THE INVENTION

1. Field of the Invention

The present invention relates generally to generic enclosure systems (GES) for the containment of microgravity experiments and other physical and chemical reactions designed to take place under microgravity environments, and, more particularly, to an improved apparatus having a double level of containment for safely and efficiently growing crystals such as protein crystals by the liquid-liquid diffusion method or for performing other methods that will be advantageously conducted under microgravity conditions.

2. Description of the Related Art

It has previously been known to construct and utilize devices capable of performing specific methods under a zero-gravity or microgravity environment. For example, the National Aeronautics and Space Administration (NASA) has previously constructed and utilized a device known as the “Protein Crystallization Apparatus for Microgravity” or “PCAM”, and the PCAM devices have been used in space, such as during various Space Shuttle missions. Another device for performing experiments and chemical reactions under zero gravity or microgravity environments has been known as the “Diffusion-controlled Crystallization Apparatus for Microgravity” or “DCAM”, and the DCAM has been utilized, for example, in the “increment” experiments conducted on the Russian “Mir” space flights which take advantage of the exceptionally long orbiting opportunities presented on the Mir Space Station. These devices have proven to be highly valuable in both ground-based and flight experiment activities in zero-gravity or microgravity environments, and numerous beneficial applications have resulted from their use.

An integral requirement of these apparatuses was to be able to obtain feedback from the various microgravity experiments during flight in order to adjust the given experimental conditions. PCAMs and DCAMs, however, do not allow direct visual examination or interaction with the crystal growth process in microgravity because the mission specialists are unable to adequately view the microscopic crystals. Due to this limitation of the current hardware, with the exception of crew activation and deactivation of PCAM, further crew interaction with these microgravity experiments was discontinued.

PCAM pioneered the development of the disposable interface in flight experiment hardware. This meant that the extensive documentation and testing performed on the flight hardware could be limited to the containment housing rather than the actual cassettes within the hardware where the actual experiments were performed. Although the DCAM contained components which were disposable, each disposable unit was considered as flight hardware, requiring the usual vigorous qualifications test in safety, functionality, materials compatibility, inventory control, etc. which are extremely time consuming and costly. The development of the GES, or Generic Enclosure System, the subject of the present invention, provides a flight hardware interface which provides the required two levels of containment, thus allowing the internal components to be designated as non-flight hardware. This means that flight experiments can be rapidly developed, and deployed for testing within the approved GES envelope.

Improvements in the quality of protein crystals can in some cases be the limiting step in the determination of the atomic three-dimensional structure. Important for neutron diffraction studies, long term crystal growth is needed to provide the opportunity for large crystals to be grown. A detailed knowledge of the atomic three-dimensional structure of protein molecules is key to a fundamental understanding of biochemistry and is important in applications of structure-guided drug design.

A further limitation of the current PCAM and DCAM hardware is the inability to gain access to the microgravity experiments through the glove box interface which allows crew involvement in the optimization and documentation of experiments to produce useful crystals. This difficulty to pack and repack the experiments in microgravity is further complicated by design deficiencies of the current PCAM hardware in addition to the extensive nature of its particularly cumbersome o-ring sealing mechanism and DCAM units are integrated into a tray assembly which prevents disassembly in flight.

Therefore, the microgravity experiment industry is in great need of an apparatus having two levels of containment which easily allows the user mission specialist to gain in-flight access to the contained microgravity experiments, whereby facilitating interactive experimentation in crystal growth, an important component of the production of large high quality protein crystals.

With regard to current devices having the capability of housing assemblies for performing microgravity experiments, two specific examples currently exist. U.S. Pat. No. 5,643,540 to Carter, herein incorporated by reference, discloses an apparatus for growing protein crystals under microgravity conditions within a canister having a plurality of protein growth trays which have a number of growth chambers each having a wick, precipitating agents and well defining a protein growth receptacle. Further, U.S. Pat. No. 5,641,681 to Carter, herein incorporated by reference, also discloses a device and method for detecting optimum protein crystallization conditions and for growing protein crystals in either 1 g or microgravity environments having a housing containing an orifice therein for providing fluid communication between chambers for containing crystallization solutions. However, neither of these references disclose a generic containment device having two levels of containment to provide the properly approved interface for the safe conduct of experiments in microgravity, preventing undesirable leakage of liquids or gases into the closed environment of an orbiting spacecraft which may pose hazards to the crew and equipment. While the focus of the example is in facilitating the conduct of microgravity experiments in protein crystal growth, the GES device can be used as a flight approved envelope or stowage compartment for any number of functions, including storage of food, medical samples, etc.

Therefore, the problem of supplying an apparatus for performing microgravity experiments, chemical reactions, or general stowage of items, e.g., foods, medical supplies or blood/urine samples, etc., in a microgravity environment which has two levels of containment, provides for the easy viewing and convenient access and stowage of microgravity experiments, and which is capable of sustaining long term crystal growth resulting in the growth of large crystals, remains unresolved. In addition, it is thus highly desirable to provide an apparatus which can avoid leaks since a leaking microgravity experiment containment apparatus can result in jeopardizing the safety of the crew and equipment of an orbiting spacecraft.

### SUMMARY OF THE INVENTION

It is thus an object of the present invention to provide an apparatus which allows the mission specialist be able to obtain feedback from the various microgravity experiments during flight in order to document the progress of each experiment for future optimization and/or adjust the given experimental conditions.

It is also an object of the present invention to provide an apparatus which can facilitate the mission specialists' ability to gain access to the microgravity experiments through the glove box interface, and more specifically, to easily be able to pack and repack the experiments in microgravity environments.

It is also an object of the present invention to provide a microgravity experiment containment canister which minimizes any possible chance of leakage into an orbiting spacecraft.

It is even further an object of the present invention to provide a growth environment capable of sustaining long term protein crystal growth, thereby facilitating the determination of protein crystal atomic three-dimensional structure.

These and other objects are provided by the present invention which comprises, in the preferred embodiment, an apparatus for the containment of a microgravity-environment assembly in which microgravity experiments or other chemical or physical reactions or processes can be carried out in a microgravity environment comprising an elongate hollow cylinder capable of housing at least one microgravity-environment assembly, said cylinder having a bottom end and a top end; at least one endcap disposed at either the bottom or top of said cylinder to provide a sealable and removable closure for the interior of said cylinder, said endcap having an o-ring for sealing against the cylinder wall to establish a first level of containment for the interior of said cylinder, and said endcap capable of activating at least one microgravity-environment assembly housed in the interior of said cylinder; at least one microgravity-environment assembly in which microgravity experiments or other chemical or physical reactions or processes can be carried out in a microgravity environment, said assembly disposed between said bottom end and said top end of said cylinder; and an additional o-ring disposed in at least one end of said cylinder which contains an endcap, said additional o-ring being capable of providing an additional seal against the endcap so as to provide a second layer of containment for the interior of the cylinder.

In addition, the objects of the present invention are achieved by an alternate embodiment of the present invention which comprises an apparatus for the containment of experiments in microgravity environments comprising a hollow canister of a length and diameter to accommodate a microgravity-environment assembly wherein microgravity experiments or other chemical reactions or processes can take place in a microgravity environment, said canister having a bottom end and a top end and having at least one endcap at either the bottom or top of said canister for enclosing said microgravity-environment assembly, said endcap having a first o-ring capable of sealing against the canister wall when inserted into said canister to provide a first level of containment of the contents of said canister; at least one assembly for performing said experiments in a microgravity environment disposed in said canister between said bottom end and said top end; and a second o-ring disposed in at least one end of said canister containing an endcap, said second o-ring capable of sealing against said endcap by compression so as to provide a second level of containment of the contents of said canister.

Even further, the present invention relates to methods for performing microgravity experiments and other chemical reactions and processes in a microgravity environment, such as zero-gravity space, by utilizing the apparatuses of the present invention.

Further features and advantages of the present invention will be set forth in, or apparent from, the detailed description of preferred embodiments thereof which follows.

### BRIEF DESCRIPTION OF THE DRAWINGS

The foregoing objects and advantages of the present invention for a new and improved apparatus and method of containing experiments in microgravity environments will be more readily understood by one skilled in the art by referring to the following detailed description of the preferred embodiments and to the accompanying drawings which form part of this disclosure, and wherein:

FIG. 1 is a perspective partially exploded view of an apparatus in accordance with the present invention utilizing a vapor diffusion tray (VDT) or (the disposable interface component of the PCAM) as the microgravity-environment apparatus contained in the canister of the present invention.

FIG. 2a is a view of the elements of a vapor diffusion tray (VDT) as would be utilized in the canister of the present invention, including an elastomeric cover and an actuation plate.

FIG. 2b is a view of an assembled vapor diffusion tray (VDT) as would be utilized in the canister of the present invention, with the elastomeric cover and an actuation plate in place.

FIG. 3 is a view of the apparatus of the present invention including the cylinder, a plurality of counter-diffusion cells (CDCs), and a handheld tool which may be utilized to open the apparatus of the present invention.

FIG. 4 is a side, partially cutaway view of an apparatus in accordance with the present invention with the counter diffusion cells (CDCs) in place.

FIG. 5 is a top view of the apparatus of the present invention including the rack for integrating the GES system of the invention in a thermal enclosure system.

FIG. 6 is a cross-sectional view along line A-A of the apparatus of FIG. 5.

FIG. 7 is a side mechanical view of the cylinder of the apparatus of the present invention.

### DETAILED DESCRIPTION OF THE PREFERRED EMBODIMENTS

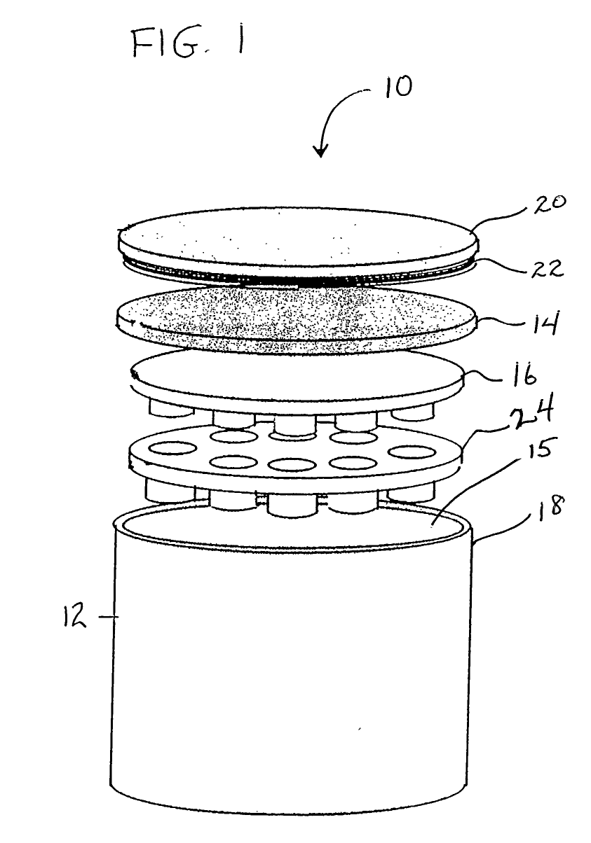

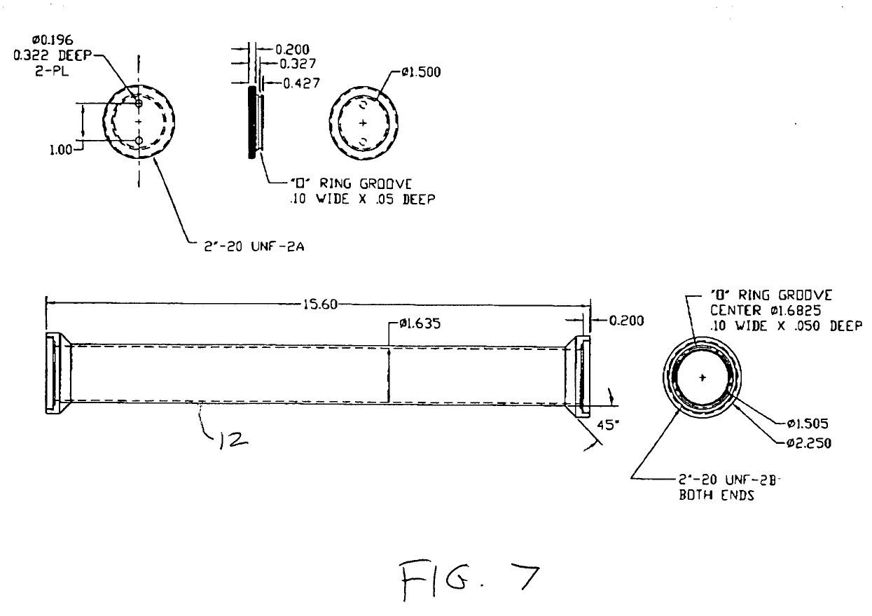

In accordance with the present invention, an apparatus is provided which can contain microgravity-environment assemblies that can be utilized when the microgravity state is achieved, such as when a space flight achieves a microgravity orbit, and such assemblies can be utilized to carry out microgravity experiments or to perform other processes, such as protein crystallization, which are advantageously carried out in microgravity or a microgravity environment. As best shown in FIGS. 1 and 7, in the preferred embodiment, this apparatus 10 comprises a suitable cylinder or canister 12, which is also known as the “Generic Enclosure System” or “GES”, of a size so as to be able to contain a plurality of microgravity assemblies housed in the interior of the cylinder. The cylinder should be constructed of a sturdy material that will be able to withstand the stresses involved in achieving a zero gravity or microgravity environment, such as would be present if the apparatus is housed in a space vehicle such as a Space Shuttle or other rocket-powered vehicle which achieves high speeds in order to escape the Earth's atmosphere and achieve a microgravity orbit and/or stowage aboard the International Space Station. Accordingly, it is preferred that the cylinder 12 be constructed of aluminum, polycarbonate, polysulphone or other suitable chemically resistant materials.

In one of the preferred embodiments, the cylinder 12 preferably is constructed with at least one end having a removable and sealable opening 15, which is preferably sealed by means of an annular endcap 20 which fits at either one or both ends of the cylinder 12, and which may attached and seal to the end of the cylinder in any number of conventional ways such as a screw/threading arrangement. The endcap 20 is preferably sealable and removable so as to create a closure which can withstand the rigors of space flight, yet can be readily opened, such as by a hand wrench, when it is desired to manipulate, initiate, or otherwise simply visualize a microgravity experiment or process being conducted in the assemblies housed in cylinder 12. For example, in the preferred use, the assemblies are intended to be accessed and activated when a zero-gravity or microgravity environment is achieved. In the preferred embodiment, the endcap 20 has a first o-ring 22 which, when inserted into the GES canister 12, seals against the canister wall 18 providing a first level of containment. A second o-ring 24 is also positioned at the end of the canister 12 at the same end or end containing a removable endcap closure, and this second o-ring seals against the endcap 20 by compression providing a second level of containment.

In a particularly preferred embodiment, the endcap 20 is disposed in the cylinder 12 so as to be able to activate one or more microgravity-environment assemblies housed in the container in which a microgravity experiment or other procedure intended to be carried out in a microgravity environment can take place. In the desired embodiment, it is preferred that an actuator system, including actuator 14 and actuator plate 16 be employed, and this actuator system is disposed in cylinder 12 so that the actuator 14 is in direct or indirect contact with endcap 20 and the actuator plate 16 is adjacent to a microgravity-environment assembly, such as vapor diffusion tray (or “VDT”) 24. It is also preferred that the actuator plate 16 be configured so that it will allow the activation of the particular microgravity-environment assembly being utilized when a desired time is reached, e.g., the zero-gravity or microgravity orbit is obtained, yet will also prevent the inadvertent activation of the assembly 24 until such time as the proper gravitational conditions are attained.

In the embodiment shown in FIG. 1, one or more vapor diffusion trays 24 may be housed (or stacked if multiple trays are present) in cylinder 12 together in direct or indirect contact with interleaving actuator plates 14 and 16 which form the actuator system of the present invention. This system is an improvement over previous arrangements such as the elaborate gear/activator mechanisms utilized in the prior art PCAM tray enclosures, and in the present invention, a precisely machined spacer (actuator) plate 16 is used at the final assembly stage. In the preferred embodiment, once the endcap 20 is screwed into place at the sealable end of the cylinder 12, the actuator plate 16 is designed to depress and seal off all of the individual chambers of the vapor diffusion tray 24, and this represents the deactivated state of the hardware.

In use, the operator may open the endcap so as to activate the microgravity-environment assemblies, and this is preferably done by unscrewing the endcap in the glovebox, or other suitable holding or stowing location on the vehicle achieving the microgravity environment, such as by means of a handheld wrench or other similar tool that can open the cylinder 12. In the preferred manner of use, the operator simply removes the actuator or spacer plate 16 from the cylinder which puts the hardware in the activated state, and allows microgravity experiments or other microgravity processes and reactions to take place. At this stage, the operator may reseal the cylinder 12 by screwing the endcap back on the cylinder by any suitable manner, and the microgravity-environment assemblies housed inside cylinder 12 may be left sealed in the activated state until such time as it is desired to end the microgravity processes and reload the device for reentry into Earth's atmosphere.

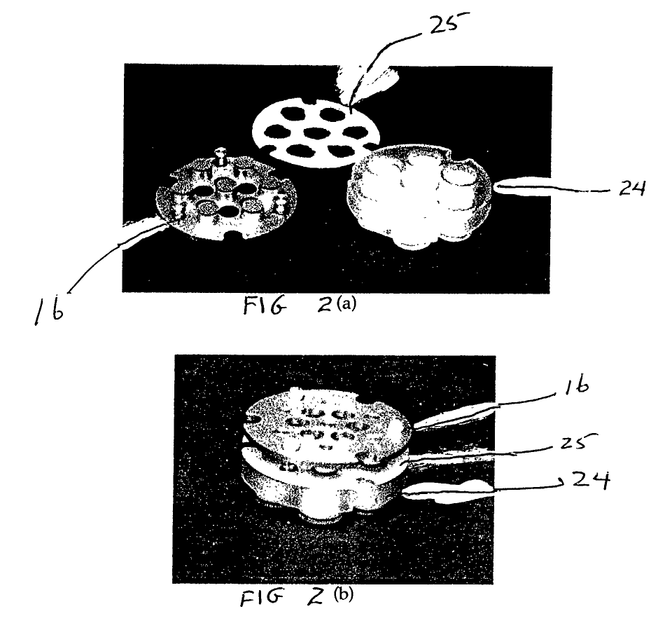

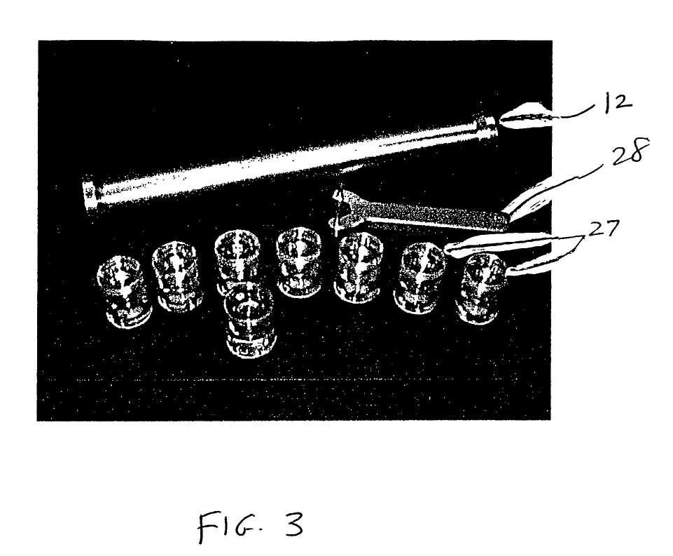

As best shown in FIGS. 2a and 2b, one of the assemblies that may be housed in the apparatus of the present invention is a vapor diffusion tray 24. As shown in FIG. 2a, the vapor diffusion tray apparatus to be utilized in the present invention comprises vapor diffusion tray 24, elastomeric cover 25, and the actuator plate 16 as described above. In FIG. 2b, the vapor diffusion tray apparatus in assembled form is shown with the elastomeric cover 25, disposed directly on top of the vapor diffusion tray 14, and the actuator plate 16 in place as would be the case when the VDT is stowed before use.

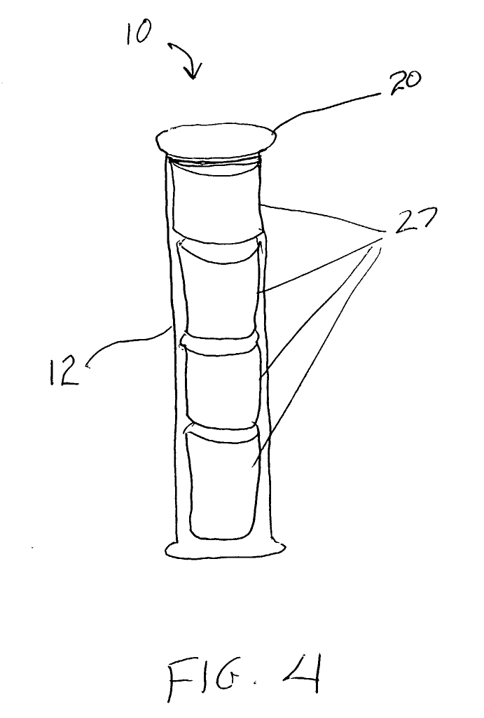

In an alternative embodiment, the hollow cylinder or canister 12 of the present invention can also be utilized to house a microgravity assembly which comprises a counter-diffusion cell (or “CDC”), as best shown in FIG. 3. In this embodiment, the canister of cylinder 12 is sized so as to contain one or more microgravity-environment assemblies, and in this case, the assembly comprises counter-diffusion cell 27, several of which are shown in FIG. 3, and these counter-diffusion cells are designed so as to be stackable one on top of the other and to fit snugly inside the cylinder 12 of the present invention. Also shown in FIG. 3 is handheld tool 28, which is preferably a wrench or other suitable tool that can be used to readily unscrew the endcap 20 of the cylinder 12 when it is desired to access or activate the enclosed microgravity-environmental devices. In addition, a side, partially cutaway view of the CDCs 27 stacked and enclosed in cylinder 12 with the endcap 20 in sealed position is shown in FIG. 4.

Accordingly, in the preferred manner of operation, the apparatus of the present invention may be operated in order to conduct interactive microgravity experiments or other chemical or physical processes desirably conducted in a microgravity environment by first loading one or more microgravity-environment assemblies 24 into the hollow cylinder 12, and affixing the endcap 20 to seal the enclosure. In the preferred embodiment, the apparatus will also contain actuator plates which will keep the microgravity assemblies from being activated prior to the time that a microgravity environment is achieved, and the assemblies are preferably stowed and sealed in inactive position. At such time as a zero-gravity or other microgravity environment is achieved, the device is opened by unscrewing or otherwise removing endcap 20 so that the microgravity processes or experiments can take place. In the preferred embodiment, once the device is opened and the end cap is removed, other means to prevent activation, such as actuator plate 16, are preferably removed, and the actuated microgravity assemblies will carry out the desired processes and/or experiments. At this point, the device may be temporarily resealed such as by screwing in endcap 20 but without replacement of the actuator plate 16 so that microgravity experiments and processes can be carried out in the sealed cylinder 12. When it is desired to complete the experiments or processes, the apparatus of the present invention may be closed by resealing the endcap, and at this point, the actuator plate 16 may also be put back in place so as to maintain the microgravity assemblies in the inactivated state for the return trip.

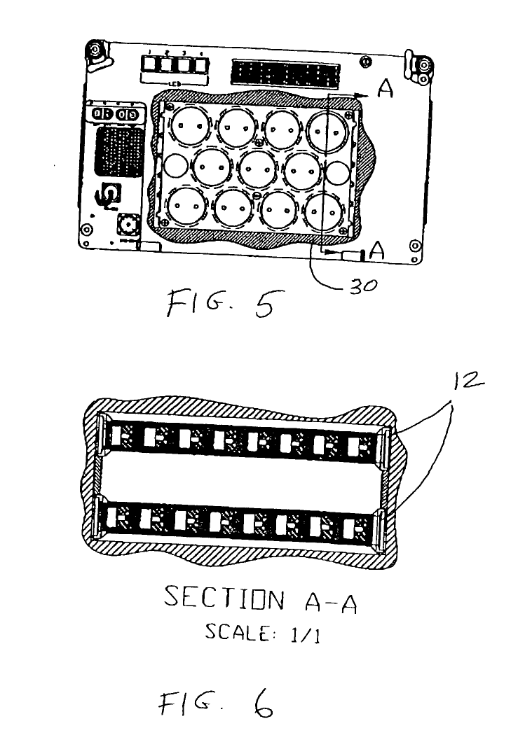

During a space flight, the present apparatus may be stored in a variety of suitable locations, such as an ambient locker. In one such embodiment, the mission specialist aboard the space flight removes the stowed canister, such as the GES including VDT assemblies, from the locker along with the handheld wrench and a rack, and then can place these items in a “glove box”, a device wherein the assemblies may be manipulated safely and efficiently. In the preferred embodiment, the mission specialist can use the handheld wrench to remove at least one endcap from the present invention so as to allow access to the VDT microgravity-environment assemblies. In other embodiments, endcaps may be located at both ends of cylinder 12, and in this case, the other end cap may also be removed if it is required to slide the VDTs out of the bottom of the present apparatus for use. As shown in FIGS. 5 and 6, the cylinders 12 of the invention can be placed in rack 30, and the rack 30 may be placed in a glove box during a space flight so that cylinders 12 may be removed or otherwise manipulated as needed.

The VDTs used in the enclosure of the present invention can be selected and removed from the cylinder one at a time if so desired for visual and microscopic observations. In general, the mission specialist transcribes the VDT number and any relevant observations into an experiment log book and, if desired, when a protein crystallization process is being carried out in the VDTs, the protein crystals can be photographed. When optimization of conditions is required, new VDTs can be loaded with the appropriate proteins and precipitants. At the completion of all observations, recordations, and experiment adjustments, the VDTs and actuators are gently replaced into the present invention and the two o-rings are carefully inspected before replacing the end caps. The number of times to monitor the GES/VDT for protein crystal growth is variable and will depend of the availability of crew interaction and the overall length of the mission.

The present invention is suitable for any number of future flight development programs. Through the ability to observe protein crystal growth and measure equilibrium rates in microgravity afforded by the present invention, scientists will have a better understanding of the microgravity performance. In terms of dimensions, any apparatus which is sized to house suitable microgravity assemblies may be suitable for use in the present invention, and it is preferred that the cylinder of the invention be sized to accommodate various NASA glove boxes and middeck payloads. In one particularly preferred embodiment, the cylinder of the present invention preferably measures 15.75 inches in length and 2.25 inches in diameter. The apparatus can also be housed during space flight in a thermal system having a means for temperature control or an ambient middeck locker. Preliminary leak tests indicate that the two levels of containment of the present invention far exceed current middeck or International Space Station experiment requirements.

The number of experiments chosen for a particular flight is entirely flexible. The present invention can be stowed in a variety of configurations from a single canister with three or four assemblies to twenty or more canisters of ten assemblies in a locker packed with foam or any other suitable protective material. Therefore, the present invention possesses the potential of more than five hundred individual experiments capable of being performed in microgravity environments.

The proteins chosen for the glove box experiments in microgravity environments will vary depending on the availability of the particular protein, the length of time available for protein crystal growth, and the temperature of the microgravity experiment (e.g., ambient, 22° C., 420 C.). The present invention can be housed in either a temperature controlled system, such as the Single-Locker Thermal Enclosure System (STES), or in a standard ambient middeck locker in a space vehicle or shuttle.

The present invention far surpasses the prior hardware designs concerning performance, experiment capacity and safety by providing three advantages over the prior hardware. First, the preferred embodiment of the present invention provides an apparatus which allows the mission specialist to interact with the crystal growth process in microgravity through the glove box interface to obtain feedback from the various microgravity experiments during flight allowing the specialist to adjust the given experimental conditions. Second, the preferred embodiment of the present invention is an apparatus which sufficiently contains microgravity experiments by providing two separate levels of containment. Third, the preferred embodiment of the present invention provides a growth environment capable of sustaining long term protein crystal growth, thereby facilitating the determination of the protein crystals' atomic three-dimensional structure.

As indicated above, in addition to the use of VDTs as the microgravity-environment assembly, the present apparatus may also enclose an alternative microgravity device such as Counter Diffusion Cells (CDCs). This embodiment of the present invention is thus also referred to as the “GES/CDC”, such as observed in FIGS. 3 and 4. The GES/CDC has the capacity to contain a plurality of counter diffusion cells, e.g., eight counter-diffusion cells, and each of these CDCs can be passively programmed to grow crystals by dialysis or bulk methods for the production of large quantities of large protein crystals of high quality for neutron and x-ray diffraction.

In addition to the features and elements described above, the GES/CDC may also be comprised of a central housing having a primary precipitant reservoir and a secondary precipitant reservoir, the primary precipitant reservoir being larger and positioned lower in the canister than the secondary precipitant reservoir. Selection of these inserts provides greater experimental variability than the earlier DCAM predecessor. The primary precipitant reservoir and the secondary precipitant reservoir are separated by a gel infused plug. The central housing is sealed with at least one end cap being either flat or including, for example, 50 μl microdialysis button. Flat endcaps are commonly used for bulk or batch liquid-liquid diffusion methods while endcaps having such standard proportioned microdialysis buttons are commonly used for dialysis and liquid-liquid diffusion methods.

As with the GES/VDT embodiment described above, the GES/CDC embodiment is ideally sized so that it can be stored easily on a space vehicle, such as in the ambient locker. In the preferred process of employing the GES/CDC embodiment, the mission specialist will remove the stowed GES/CDC from the locker and place it in a device wherein the apparatus can be manipulated, such as a glove box. In this embodiment, the mission specialist again may use a handheld wrench to remove one endcap from the present invention to allow access to the CDCs, and in an embodiment wherein two endcaps are used, the other end cap will only be removed in those circumstances wherein it is required to slide the CDCs out of the present invention out of the bottom of the cylinder into the microgravity environment. The CDCs can be selected and removed from the present invention one at a time and placed in a rack having Velcro attached to its bottom and which is attached to the glove box for both visual and microscopic observations. Such observations may include protein crystal growth, appearance of precipitant, appearance of bubbles, color changes in the solution of crystals, and sample acquisition for future measurements of refractive indices. The mission specialist transcribes the CDC number and any relevant observations into the experiment log book and, if desired, the protein crystals can be photographed. At the completion of all observations, recordations, and experiment adjustments, the CDCs are gently replaced into the present invention and the present invention in addition to all associated equipment are stowed away until further observations are necessary. The number of times to monitor the GES/CDC for protein crystal growth is variable and will depend of the availability of crew interaction and the overall length of the mission.

The CDCs used in the present invention preferably operate by utilizing the principle of counter-diffusion with an exchangeable fuse or gel plug acting as the diffusion-limited barrier separating the primary and secondary reservoirs during 1 g applications and launch scenarios. The length and diameter of the fuse act as a means to passively program the concentration gradient and therefore offers a reliable means to control the approach to critical supersaturation for both batch and dialysis applications in protein crystal growth. Equilibrium rates are also a function of the concentration gradient between the reservoirs, as well as the diffusion coefficients of the solutes. Consequently, the experimentor can program the equilibration rate individually for each CDC to operate over periods from several days to several months depending on the choice of fuse and other experimental conditions. Activation of the individual CDC units is set by the gel barrier type upon loading and does not require further crew interaction for these purposes.

As indicated above, the present invention thus provides a method of conducting experiments in microgravity environments comprising three main steps. First, the mission specialist places an assembly for performing microgravity experiments, such as growing protein crystals by dialysis or bulk methods, into the cylinder or GES. Second, the mission specialist, at specific time intervals, removes the GES to the glovebox, opens the endcap and documents the crystallization progress of each CDC while the GES is in the microgravity environment. Third, the mission specialist replaces the CDCs into the GES and reseals the endcap.

Although the invention has been described above in relation to preferred embodiments thereof, it will be understood by those skilled in the art that variations and modifications can be effected in these preferred embodiments without departing from the scope and spirit of the invention.

What is claimed is:

1. An apparatus for the containment of a microgravity-environment assembly in which microgravity experiments or other chemical or physical reactions or processes can be carried out in a microgravity environment comprising:
(a) an elongate hollow cylinder capable of housing at least one microgravity-environment assembly, said cylinder having a bottom end and a top end;
(b) at least one endcap disposed at either the bottom or top of said cylinder to provide a sealable and removable closure for the interior of said cylinder, said endcap having an o-ring for sealing against the cylinder wall to establish a first level of containment for the interior of said cylinder, and said endcap capable of activating at least one microgravity-environment assembly housed in the interior of said cylinder;
(c) at least one microgravity-environment assembly in which microgravity experiments or other chemical or physical reactions or processes can be carried out in a microgravity environment, said assembly disposed between said bottom end and said top end of said cylinder; and
(d) an additional o-ring disposed in at least one end of said cylinder which contains said endcap, said additional o-ring being capable of providing an additional seal against the endcap by compression so as to provide a second layer of containment for the interior of the cylinder.

2. The apparatus according to claim 1 wherein said assembly comprises a vapor-diffusion tray.

3. The apparatus according to claim 1 further comprising at least one actuator plate in direct or indirect contact with said endcap and disposed adjacent to said microgravity-environment assembly such that said actuator plate is capable of actuating said assembly when said endcap is removed from said cylinder.

4. The apparatus according to claim 1 wherein the cylinder is designed to house a plurality of microgravity-environment assemblies.

5. The apparatus according to claim 4 wherein the plurality of assemblies are disposed in stacked relationship one above the other in the interior of the cylinder.

6. The apparatus according to claim 1 wherein the cylinder is of a size to accommodate a glovebox of middeck payload.

7. The apparatus according to claim 1 wherein the endcap may be removed by means of a handheld wrench.

8. The apparatus according to claim 1 wherein said assembly comprises a counter-diffusion cell.

9. The apparatus according to claim 1 wherein the assembly is a device which is used to grow crystals in microgravity environments.

10. The apparatus according to claim 9 wherein the crystals may be grown in the device by means of dialysis or bulk methods.

11. The apparatus according to claim 1 wherein the cylinder is housed in a thermal system having a means for temperature control.

12. The apparatus according to claim 1 wherein the cylinder is comprised of a material capable of withstanding the stresses associated with being transported through the Earth's atmosphere in order to reach a microgravity environment outside of the Earth's atmosphere.

13. The apparatus according to claim 1 in combination with a rack wherein the cylinder can be stored, then opened and manipulated during a space flight.

14. The apparatus according to claim 13 wherein the rack can store a plurality of cylinders.

15. A method of performing an interactive experiment or other chemical or physical process in a microgravity environment comprising the steps of:
(a) placing an assembly for performing microgravity environment processes in an apparatus as claimed in claim 1;
(b) opening the endcap so as to actuate the device and allow the processes to take place when the apparatus is in a microgravity environment; and
(c) closing the device and replacing the endcap when the processes are completed.

16. The method of performing an interactive process in a microgravity environment according to claim 15 wherein the device for performing said microgravity environment process comprises a vapor diffusion tray.

17. The method of performing an interactive process in a microgravity environment according to claim 15 wherein the device for performing microgravity environment processes comprises a counter-diffusion cell.

18. The method of performing an interactive process in a microgravity environment according to claim 15 wherein said process comprises growing protein crystals.

19. The method of performing an interactive process in a microgravity environment according to claim 18 wherein said process comprises growing protein crystals by dialysis or bulk methods.

20. An apparatus for the containment of experiments in microgravity environments comprising
(a) a hollow canister of a length and diameter to accommodate a microgravity-environment assembly wherein microgravity experiments or other chemical reactions or processes can take place in a microgravity environment, said canister having a bottom end and a top end and having at least one endcap at either the bottom or top of said canister for enclosing said microgravity-environment assembly, said endcap having a first o-ring capable of sealing against the canister wall when inserted into said canister to provide a first level of containment of the contents of said canister;
(b) at least one assembly for performing said experiments in a microgravity environment disposed in said canister between said bottom end and said top end; and
(c) a second o-ring disposed in at least one end of said canister containing an endcap, said second o-ring capable of sealing against said endcap by compression so as to provide a second level of containment of the contents of said canister.

21. The apparatus according to claim 20 wherein said microgravity-environment assembly comprises a counter diffusion cell, said cell having a central housing sealed by an endcap, said central housing comprising a primary precipitant reservoir and a secondary precipitant reservoir.

22. The apparatus according to claim 21 wherein said primary precipitant reservoir is larger and positioned lower in said canister than said secondary precipitant reservoir.

23. The apparatus according to claim 21 wherein said counter diffusion cell endcap includes a 50 μl microdialysis button.

24. The apparatus according to claim 20 wherein the canister is designed to house a plurality of said assemblies.

25. The apparatus according to claim 24 wherein the said plurality of assemblies are disposed in stacked relationship one above the other in the interior of the canister.

25. The apparatus according to claim 21 wherein said endcap may be removed by means of a handheld wrench.

26. The apparatus according to claim 21 wherein said canister is stowed in an ambient middeck locker.

27. The apparatus according to claim 21 wherein said microgravity-environment assembly is a device which is used to grow protein crystals.

28. The apparatus according to claim 27 wherein said protein crystals may be grown in the device by means of dialysis.

29. An apparatus for the containment of a microgravity-environment assembly in which a microgravity experiment or other chemical or physical reaction or process can be carried out in a microgravity environment comprising:
(a) an elongate hollow cylinder capable of housing at least one microgravity-environment assembly, said cylinder having a bottom end and a top end;
(b) at least one endcap disposed at either the bottom or top of said cylinder to provide a sealable and removable closure for the interior of said cylinder, said endcap having an o-ring for sealing against the cylinder wall to establish a first level of containment for the interior of said cylinder, and said endcap capable of activating at least one microgravity-environment assembly housed in the interior of said cylinder;
(c) at least one actuator plate in direct or indirect contact with said endcap and disposed adjacent to said microgravity-environment assembly such that said actuator plate is capable of actuating said assembly when said endcap is removed from said cylinder.
(d) at least one microgravity-environment assembly in which microgravity experiments or other chemical or physical reactions or processes can be carried out in a microgravity environment, said assembly disposed between said bottom end and said top end of said cylinder; and
(e) an additional o-ring disposed in at least one end of said cylinder which contains said endcap, said additional o-ring being capable of providing an additional seal against the endcap by compression so as to provide a second layer of containment for the interior of the cylinder.

30. A method of performing a microgravity experiment or other chemical or physical reaction or process in a microgravity environment comprising the steps of:
(a) placing an assembly for performing a microgravity experiment or other chemical or physical reaction or process in microgravity environments in an apparatus according to claim 29;
(b) opening the endcap and removing the actuator plate to allow the processes to take place when the apparatus is in a microgravity environment; and
(c) replacing the actuator plate when the processes are completed and resealing the endcap so as to maintain the assemblies in an inactivated state.

31. The method according to claim 30 further comprising an interim step wherein said endcap is put back in place to seal the cylinder without the inclusion of the actuator plate so that the microgravity experiments or other chemical or physical reactions or processes can be carried out in a sealed enclosure.

32. The method according to claim 30 wherein said experiments comprise growing protein crystals.

33. A method of conducting experiments in microgravity environments according to claim 32 wherein said protein crystals are grown by dialysis or bulk methods.
